(19) United States
(12) Patent Application Publication
(10) Pub. No.: US 2013/0059237 A1
(43) Pub. Date: Mar. 7, 2013

(54) METHOD FOR FABRICATING A PHOTOMASK FOR EUV LITHOGRAPHY

(71) Applicant: HYNIX SEMICONDUCTOR INC., Gyeonggi-do (KR)

(72) Inventor: Young Dae Kim, Cheonan-si (KR)

(73) Assignee: HYNIX SEMICONDUCTOR INC., Gyeonggi-do (KR)

(21) Appl. No.: 13/651,048

(22) Filed: Oct. 12, 2012

Related U.S. Application Data
(62) Division of application No. 12/491,598, filed on Jun. 25, 2009.

(30) Foreign Application Priority Data
Dec. 26, 2008 (KR) 10-2008-0134835

(51) Int. Cl. G03F 1/24

(52) U.S. Cl. 430/5

(57) ABSTRACT

A photomask for extreme ultraviolet (EUV) lithography includes: a substrate; a reflection layer disposed over the substrate and reflecting EUV light incident thereto; and an absorber layer pattern disposed over the reflection layer to expose a portion of the reflection layer and comprising a material having an extinction coefficient (k) to EUV radiation higher than that tantalum (Ta).

### CROSS-REFERENCE TO RELATED APPLICATION

This is a division of U.S. application Ser. No. 12/491,598 filed Jun. 25, 2009, which claims the priority benefit under 35 USC §119 of Korean patent application No. 10-2008-0134835 filed Dec. 26, 2008, the entire respective disclosures of which are incorporated herein by reference.

### BACKGROUND OF THE INVENTION

The invention relates generally to a photomask and a method for fabricating the same and, more particularly, to a photomask for an extreme ultraviolet lithography with a structure capable of preventing a shadow effect and a method for fabricating the same.

In a process for fabricating a semiconductor device, a lithography process is an essential process for forming a circuit pattern by irradiating light (i.e., radiation) on a substrate coated with a photoresist. Laser has been mainly used as a light source for the lithography, but now shows an optical limitation as a critical dimension (CD) of the pattern is sharply reduced due to high degrees of integration of semiconductor devices. Accordingly, noble light sources such as extreme ultraviolet (EUV), electron beam, X-ray, and ion beam radiation have been developed, among which the EUIV and the electron beam have attracted public attention as a light source for the next generation exposure technology.

In the lithography process currently used or under development, a KrF (248 nm) light source or an ArF (193 nm) light source is used and a transmissive mask in which a light shielding pattern, e.g. made of chromium (Cr), formed on a blank substrate is employed. However, a wavelength in the EUV range (e.g., around 13.4 nm) is used in the EUV lithography and a reflective mask, which is different from the transmissive mask, is used in the exposure technology using EUV light since almost materials have a large light absorption in the EUV range. In the reflective mask, since a pattern of the reflective mask is divided into a reflection layer and an absorber layer, various methods for contrast improvement used in the transmissive mask, for example, methods using a strong phase shift mask (PSM), a rim type strong PSM, and a half tone PSM cannot be employed and the lithography process is performed simply using reflection and absorption of EUV light.

FIG. 1 is a cross-sectional view illustrating a conventional mask for EUV lithography.

Referring to FIG. 1, a reflection layer 110 is disposed on a transparent substrate 100, a buffer layer 120 which functions as a passivation film upon pattern correction is disposed on the reflection layer 110, and an absorber layer 130 is disposed on the buffer layer 120. The absorber layer 130 and the buffer layer 120 are patterned to define a pattern to be realized, thereby partially exposing a surface of the reflection layer 110.

As such, the reflective mask for EUV lithography includes various layers and the EUV light is reflected on the surface of the reflection layer 110 and absorbed in the absorber layer 130 to form a pattern.

The reflection layer 110 has a multi-reflection layer structure in which different kinds of films such as molybdenum (Mo), silicon (Si), beryllium (Be), and silicon (Si) are alternatively stacked. The absorber layer 130 is made of a compound, e.g. tantalum nitride (TaN), capable of absorbing the EUV light and containing tantalum (Ta). This is because it is easy to perform, on tantalum, a plasma etching using fluorine-based radical that is widely used in a semiconductor fabrication process and thus a mask fabrication process can be facilitated.

However, since tantalum has a relatively low EUV light absorption, the absorber layer made of the tantalum compound should have a thickness of at least 70 nm to generate an EUV reflectivity difference from the reflection layer, thereby being capable of maintaining an energy contrast required in EUV lithography. Therefore, in order to employ an EUV mask including an absorber layer made of a tantalum compound, a problem that a difference in a pattern CD is generated by a shadow effect should first be solved. The shadow effect means a pattern distortion caused by variation in a shading degree of the mask pattern according to a direction of incidence of the EUV when the EUV is irradiated on a highly stepped absorber layer pattern.

FIGS. 2A and 2B are views explaining a shadow effect resulted in a prior art EUV lithography process.

FIG. 2A shows a case that the EUV is incident vertically to the absorber pattern, and FIG. 2B shows a case that the EUV is incident to the absorber pattern at a non-perpendicular angle. Reference numeral 200 indicates a substrate, 210 indicates a reflection layer, 220 indicates a buffer layer, and 230 indicates an absorber layer pattern.

As shown in FIG. 2A, a desired pattern can be precisely realized on a wafer when the EUV is incident vertically to the absorber layer pattern 230. But, as shown in FIG. 2B, a desired pattern is not precisely realized on a wafer due to the step between the absorber layer pattern 230 and the buffer layer 220 when the EUV is slantly incident to the absorber pattern 230 with a non-perpendicular angle. Particularly, since an angle of incidence of the EUV varies as a region on the mask where the pattern is placed, and a shape of the pattern, a CD of the pattern differs from one region to another. In the EUV lithography process, such a problem due to the shadow effect is the problem to be immediately improved since the EUV is not vertically incident but is slantly incident.

### SUMMARY OF THE INVENTION

In one embodiment, a photomask for extreme ultraviolet (EUV) lithography includes: a substrate; a reflection layer disposed over the substrate and reflecting EUV light incident thereto; and an absorber layer pattern disposed over the reflection layer so as to expose a portion of the reflection layer and made of a material having an extinction coefficient (k) to EUV higher than that of tantalum (Ta).

In another embodiment, a method for fabricating a photomask for EUV lithography includes: forming a reflection layer for reflecting EUV light incident thereto over a substrate; and forming, over the reflection layer, an absorber layer pattern for exposing a portion of the reflection layer and absorbing the EUV light using a material having an extinction coefficient (k) to EUV higher than that of tantalum (Ta).

In further another embodiment, a method for fabricating a photomask for EUV lithography includes: forming a reflection layer for reflecting EUV lght incident thereto over a substrate; sequentially forming a first polymer layer and a second polymer layer; transferring a pattern onto the first and second polymer layers; forming an undercut under the second polymer layer to expose a portion of the reflection layer; forming an absorber layer pattern for absorbing the EUV light incident thereto over the exposed surface of the reflection layer using a material having a high extinction coefficient (k) to EUV; and removing the first and second polymer layers.

### BRIEF DESCRIPTION OF THE DRAWINGS

FIG. 1 is a cross-sectional view illustrating a conventional mask for EUV lithography.

FIGS. 2A and 2B are views explaining a shadow effect resulting in an EUV lithography process.

FIG. 3 is a graph illustrating transmittances of various materials to EUV light.

FIG. 4 is a cross-sectional view illustrating a photomask for EUV lithography in accordance with an embodiment of the invention.

FIGS. 5 through 11 are cross-sectional views illustrating a method for fabricating the photomask used in EUV lithography in accordance with an embodiment of the invention.

FIGS. 12 through 14 are cross-sectional views illustrating a method for fabricating a mold used in the fabrication of the photomask for EUV lithography in accordance with an embodiment of the invention.

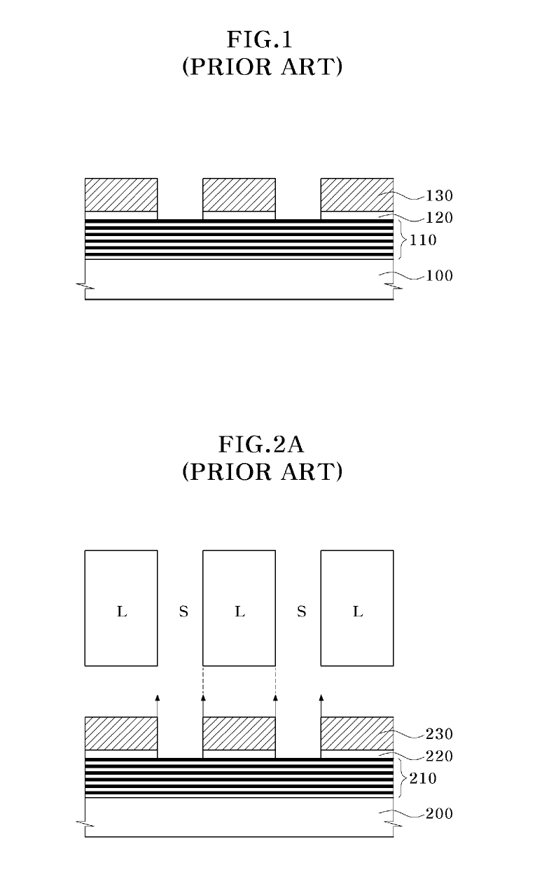

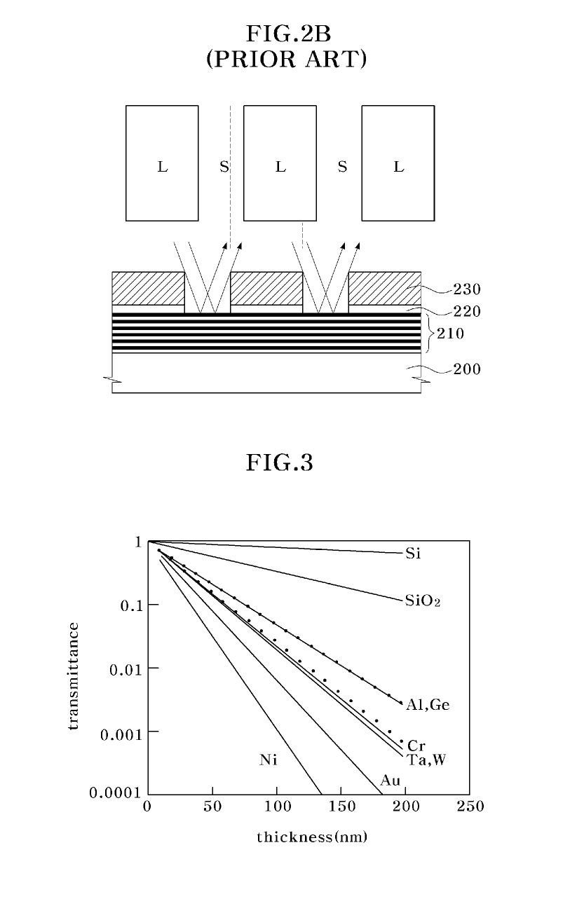

### DESCRIPTION OF SPECIFIC EMBODIMENTS

Hereinafter, a method for fabricating a photomask in accordance with the invention is described in detail with reference to the accompanying drawings.

FIG. 3 is a graph illustrating transmittances of various materials to EUV light.

Referring to FIG. 3, particularly nickel (Ni) and gold (Au) among various materials show lower transmittances as compared to tantalum (Ta), which has been widely used as a material for an absorber layer of a photomask for EUV lithography. Nickel (Ni) and gold (Au) have an EUV absorption far superior to(i.e., higher than) tantalum (Ta). Other suitable materials with relatively high EUV absorption (as compared to tantalum) include indium (In), cadmium (Cd), cobalt (Co), and platinum (Pt). When using these materials having superior EUV absorption as the material for an absorber layer, EUV absorption in the absorber layer can be raised to increase an energy contrast to EUV reflected in an adjacent reflection layer. Also, a height of the absorber layer required to have the same EUV absorption can be significantly reduced. Therefore, it is possible to significantly reduce a shadow effect according to the height of the absorber layer while meeting the absorption level required in an EUV lithography.

FIG. 4 is a cross-sectional view illustrating a photomask for EUV lithography in accordance with an embodiment of the invention.

A photomask in accordance with an embodiment of the invention includes a transmissive substrate 300, a reflection layer 310 disposed over the substrate and reflecting EUV light incident thereto, and an absorber layer pattern 340a disposed over the reflection layer 310 so to expose a portion of the reflection layer and absorbing the incident EUV light.

The substrate 300 preferaly is a substrate having a low thermal expansion coefficient, e.g. quartz.

The reflection layer 310 is formed in such a manner that a stack of a plurality of dual layers, each comprising a scattering layer 311 that scatters incident EUV light and a spacing layer 312 formed over the scattering layer 311. The scattering layer 311 preferably comprises molybdenum (Mo) and the spacing layer 312 preferably comprises silicon (Si). This dual layer formed of the scattering layer/spacing layer preferably has a thickness of about 7 nm and reflects EUV light with a wavelength of about 13 nm in accordance with the theory of a distributed Bragg reflector. Preferably, the scattering layer/spacing layer can be a stack of 30 to 40 layers.

Over the reflection layer 310, an adhesive layer to enhance adhesion between the reflection layer and the absorber layer pattern can be introduced. The adhesive layer preferably comprises chromium (Cr) or titanium (Ti) and preferably has a thickness of about 10 nm.

The absorber layer pattern 340a preferably comprises a material having an extinction coefficient (k) to EUV higher than that of tantalum (Ta). The extinction coefficient (k) is a measure of light absorption in a material, and illustrative by non-limiting examples of materials having a high extinction coefficient (k) relative to tantalum (Ta) include iron (Fe), silver (Ag), copper (Cu), zinc (Zn), nickel (Ni), indium (In), cadmium (Cd), cobalt (Co), gold (Au), and platinum (Pt). Since the absorber layer 340a comprises a material having a high extinction coefficient (k), the photomask of the invention can meet absorption requirements of EUV lithography even with a very small thickness (e.g., 20 nm to 50 nm) as compared to a conventional absorber layer including tantalum. Therefore, it is possible to significantly reduce a shadow effect due to a height of the absorber layer without lowering the energy contrast of the EUV light in the reflection layer and the absorber layer.

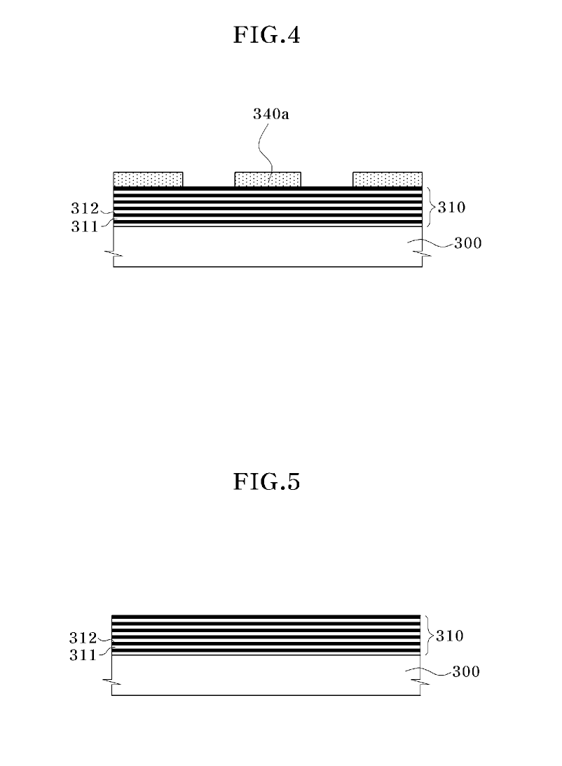

FIGS. 5 through 11 are cross-sectional views illustrating a method for fabricating the photomask used in EUV lithography in accordance with an embodiment of the invention.

Referring to FIG. 5, the reflection layer 310 is formed over the transparent substrate 300. The substrate 300 preferably is a substrate having a low thermal expansion coefficient, e.g. quartz. The reflection layer 310 preferably is formed by stacking a plurality of dual layers, each dual layer including a scattering layer 311 that scatters incident EUV light and a spacing layer 312 that spaces the scattering layers from another. The scattering layer 311 preferably comprises molybdenum (Mo) and the spacing layer 312 preferably comprises silicon (Si). The reflection layer 310 preferably has a thickness of about 7 nm and preferably includes a stack of 30 to 40 dual layers of the scattering layer 311/spacing layer 312.

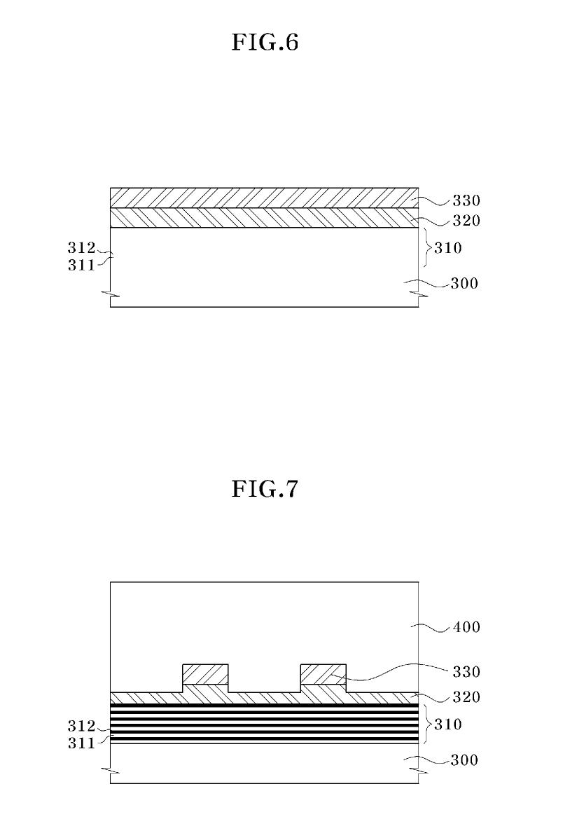

Referring to FIG. 6, a first material layer 320 and a second material layer 330 are sequentially formed over the reflection layer 310.

The first material layer 320 and the second material layer 330 are layers for subsequent formation of the absorber layer pattern using imprinting and are formed of material capable of allowing the imprinting. The imprinting is a method for realizing an engraved pattern corresponding to a circuit pattern on a target layer by imprinting a molder or a stamper having a pattern corresponding to the circuit pattern embossed on the surface thereof. Accordingly, the first material layer 320 and the second material layer 330 preferably are formed of a material having a flowability, for example, a polymer. Specifically, the first material layer 320 preferably has a flowability allowing the imprinting at room temperature without baking. An example for this material may include a polymethylglutarimide (PMGI)-based resist. The second material layer 330 preferably comprises a thermosetting polymer that is cured by heat applied upon imprinting. An example for this material is a polyimethylmethacrylate (PMMA)-based resist. The first material layer 320 and the second material layer 330 preferably are formed by spin coating. Also, the first material layer 320 and the second material layer 330 preferably are formed to a thickness allowing the imprinting using a molder in subsequent step, for example, to a thickness of 20 nm to 400 nm for the first material layer 320 and to a thickness of 20 nm to 300 nm for the second material layer 330.

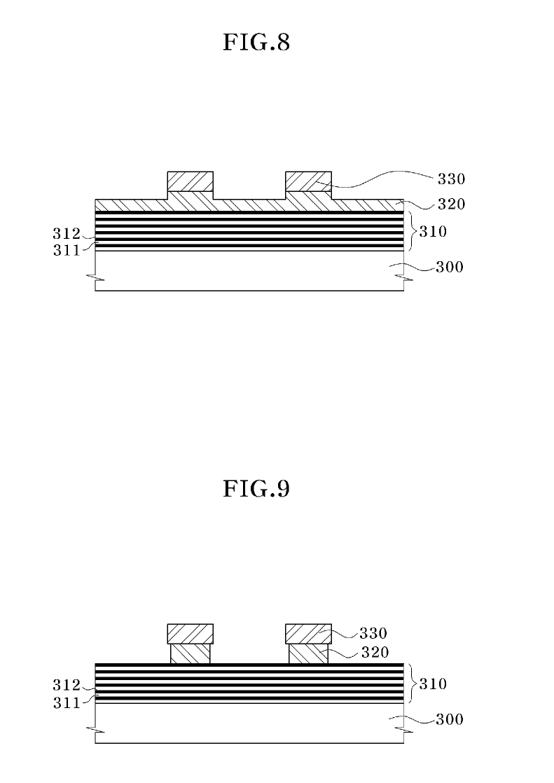

Referring to FIGS. 7 and 8, the imprinting is performed on the second material layer 330 and first material layer 320 using a prepared molder 400. Specifically, the molder formed with a pattern is placed over the second material layer 330 and then the first and second material layers are imprinted by the molder. After that, the first and second material layers are cured by radiating heat or irradiating UV. The method of curing the polymer layer is divided into heat radiation and UV irradiation. In one example, in the case that the first material layer 320 and the second material layer 330 are formed of a thermosetting polymer, the imprinting is performed at a temperature of about 60° C. with the temperature being raised to about 150° C. to heat cure the second material layer 330 and temporarily cure the first material layer 320. After that, the molder 400 is removed from the first and second material layers to thereby form an engraved pattern, which corresponds to the embossed pattern formed in the molder, on the first material layer 320 and the second material layer 330, as shown in FIG. 8.

The molder 400 used in the imprinting can be fabricated, for example, using quartz, and the fabrication method thereof is described below.

Referring to FIG. 9, a portion of the first material layer 320 is removed. In the case that the first material 320 is formed of a resist, the removal preferably is performed using a developing solution. The portion of the first material layer, which remains in the region to be formed with the absorber layer pattern, i.e. the region where the second material layer is removed, preferably is removed to form an undercut under a second material layer 330. The undercut formed under the second material layer 330 allows an etching solution to penetrate into the first material layer pattern to remove the first material layer in a subsequent process of lifting off the first and second material layer.

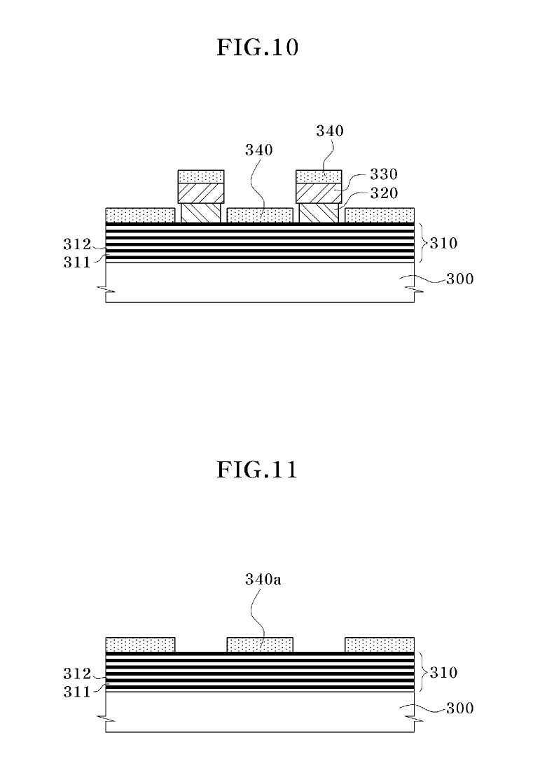

Referring to FIG. 10, a material for forming the absorber layer pattern is deposited over the resulting product, in which a portion of the reflection layer 310 is exposed, to form the absorber layer 340. The absorber layer 340 preferably is formed of a material having a high EUV light absorption characteristic, i.e. a material having a high extinction coefficient (k) to EUV relative to that of tantalum. Examples of the material may include iron (Fe), silver (Ag), copper (Cu), zinc (Zn), nickel (Ni), indium (In), cadmium (Cd), cobalt (Co), gold (Au), and platinum (Pt). The absorber layer 340 preferably is formed by physical vapor deposition (PVD) such as sputtering or chemical vapor deposition (CVD), and is preferably formed to a thickness of 20 nm to 50 nm. When the absorber layer is deposited by PVD or CVD, the absorber layer 340 is formed, as shown, over the exposed surface of the reflection layer and an upper portion of the second material layer pattern 340. Since the material with a high extinction coefficient (k) has a high EUV absorption, it is typically possible to reduce the thickness to less than half of the thickness of a conventional absorber layer including tantalum (Ta). Therefore, it is possible to significantly reduce the shadow effect generated due to the thickness of the absorber layer.

In the case that the absorber layer 340 is formed of gold (Au), the gold (Au) preferably is deposited after depositing chromium (Cr) or titanium (Ti) to a thickness of about 10 nm in order to enhance adhesiveness to a silicon (Si) layer of the reflection layer 310.

Referring to FIG. 11, a wet etching process using a chemical preferably is performed to remove the first material layer and the second material layer patterns. At this time, by removing the first material layer pattern using the chemical for etching the first material layer pattern, the second material layer pattern and the absorber layer over the second material layer pattern are also lifted off and removed together. Then, the absorber layer pattern 340a is formed over the reflection layer 310 with a thickness significantly lowered than that of a conventional pattern.

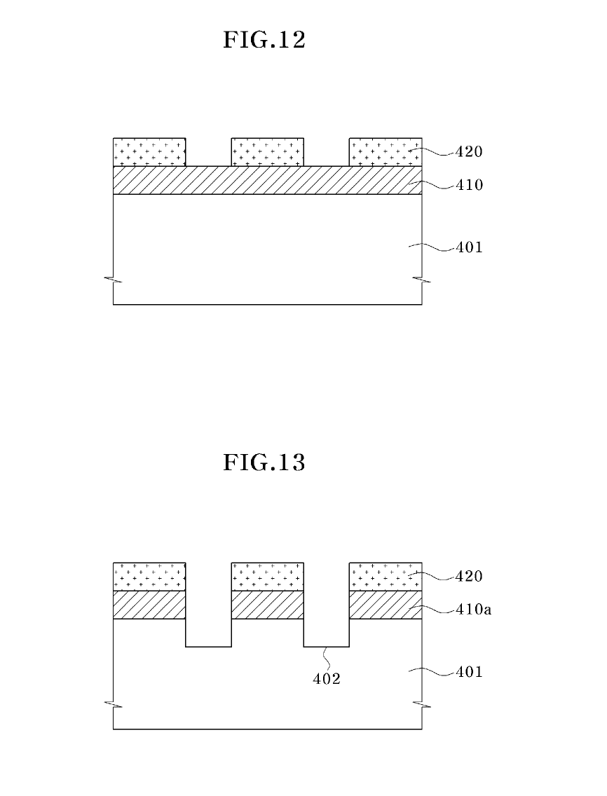

Meanwhile, an imprinting method is performed to realize an engraved pattern corresponding to a circuit pattern on a target layer by imprinting a molder or a stamper having a pattern corresponding to the circuit pattern embossed on the surface thereof. As such, a molder (or a stamper) formed with an embossed pattern corresponding to the circuit pattern is used in the imprinting method, and the embossed pattern corresponding to the circuit pattern is formed protruding from the surface of the mold. An example of a method for fabricating the molder is briefly described below with reference to FIGS. 12 through 14.

Referring to FIG. 12, a mask layer 410 is formed over a molder substrate 401. As the substrate 401, a glass substrate, a silicon substrate, or a quartz substrate can be used. The mask layer 410 is used as a mask for etching the substrate to form a pattern, and can be formed of a material having an etch selectivity to the substrate 401. In the disclosed embodiment, a chromium (Cr) film is formed over a quartz substrate. Next, a resist pattern 420 is formed over the mask layer 410. The resist pattern 420 preferably is formed by coating a conventional electron beam resist and then performing an exposure using an electron beam and development.

Referring to FIG. 13, etching on the mask layer is performed using the resist pattern 420 as a mask to form a mask pattern 410a. The substrate 401 preferably is dry etched using the mask pattern 410a as a mask to form an engraved pattern 402 in the substrate 401. The etching on the substrate 401 preferably is formed after removing the resist pattern. Dry etching preferably is used to perform the etching on the mask layer and the substrate.

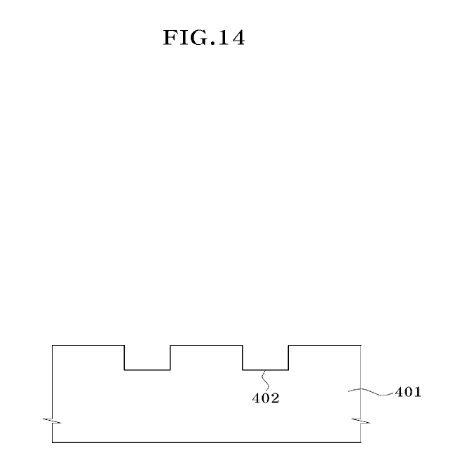

Referring to FIG. 14, the resist pattern and the mask pattern are removed to complete production of the molder formed with the engraved pattern 402. When fabricating a photomask using the molder fabricated as such, there is an advantage that a plurality of the same EUV photomasks can be formed.

As is apparent from the above description, it is possible to significantly lower the height of the absorber layer with increasing the energy contrast of the EUV in the reflection layer and the absorber layer by using a material having an EUV absorption superior to tantalum. Therefore, it is possible to reduce the shadow effect and thus minimize variation in a pattern CD due to the shadow effect. Also, it is possible to form the same mask in plural since the absorber layer pattern is formed by the imprinting method using the molder.

While the invention has been described with respect to the specific embodiments, various changes and modifications may be made without departing from the spirit and scope of the invention as defined in the following claims.

What is claimed is:

1. A method for fabricating a photomask for EUV lithography, the method comprising:
forming a reflection layer for reflecting EUV light incident thereto over a substrate; and
forming, over the reflection layer, an absorber layer pattern exposing a portion of the reflection layer and absorbing the EUV light comprising a material having an extinction coefficient (k) to EUV radiation higher than that of tantalum (Ta).

2. The method of claim 1, comprising forming the reflection layer by:
stacking, over the substrate, a plurality of dual layers, each dual layer comprising a scattering layer for scattering the incident EUV light and a spacer layer formed over the scattering layer.

3. The method of claim 1, comprising forming the absorber layer pattern by:
sequentially forming a first material layer and a second material layer over the reflection layer;
transferring a pattern onto the first material layer and the second material layer by imprinting the first material layer and the second material layer using a molder or stamper;
forming an undercut under the patterned second material layer to expose a portion of the reflection layer;
forming an absorber layer pattern for absorbing the EUV light incident thereto over the exposed surface of the reflection layer; and
removing the first and second material layers.

4. The method of claim 3, wherein the first material layer has a thickness of 20 nm to 400 nm and the second material layer has a thickness of 20 nm to 30 nm.

5. The method of claim 3, wherein each of the first material layer and the second material layer comprises a polymer.

6. The method of claim 3, wherein the first material layer comprises a material having a flowability allowing the imprinting at room temperature.

7. The method of claim 6, wherein the first material layer comprises a polymethylglutarimide (PMGI)-based resist.

8. The method of claim 3, wherein the second material layer comprises a thermosetting polymer.

9. The method of claim 3, wherein the second material layer comprises a polymethylmethacrylate (PMMA)-based resist.

10. The method of claim 3, wherein the molder or stamper comprises quartz and has a pattern embossed thereon opposite to the absorber layer pattern.

11. The method of claim 3, further comprising, before forming the absorber layer pattern, forming, over the reflection layer, an adhesive layer comprising chromium (Cr) or titanium (Ti) to enhance adhesiveness between the reflection layer and the absorber layer pattern.

12. The method of claim 3, wherein forming the undercut under the patterned second material layer to expose a portion of the reflection layer comprises: forming the undercut under the second material layer while removing the first material layer formed over the reflection layer using a wet chemical.

13. The method of claim 3, wherein forming the absorber layer pattern comprises forming an absorber layer over an entire surface of the resulting product in which the some portion of the reflection layer is exposed, and
lifting off the absorber layer formed over the second material layer upon removing the first and second material layers.

14. The method of claim 3, comprising removing the first and second material layers comprises lifting off the second material layer while removing the first material layer using a wet chemical for removing the first material layer.

15. The method of claim 1, wherein the absorber layer pattern comprises a metal selected from the group consisting of nickel (Ni), indium (In), cadmium (Cd), cobalt (Co), gold (Au), and platinum (Pt).

16. The method of claim 1, wherein the absorber layer pattern has a thickness of 20 nm to 50 nm.

17. A method for fabricating a photomask for a EUV lithography, the method comprising:
forming a reflection layer for reflecting EUV light incident thereto over a substrate;
sequentially forming a first polymer layer and a second polymer layer;
transferring a pattern onto the first and second polymer layers;
forming an undercut under the second polymer layer to expose a portion of the reflection layer;
forming an absorber layer pattern for absorbing the EUV light incident thereto over the exposed surface of the reflection layer using a material having a higher extinction coefficient (k) to EUV radiation than that of tantalum (Ta); and
removing the first and second polymer layers.
